(19) United States
(12) Patent Application Publication
(10) Pub. No.: US 2018/0341057 A1
(43) Pub. Date: Nov. 29, 2018

(54) LIGHT EMITTING DEVICE

(71) Applicant: TOKI CORPORATION, Tokyo (JP)

(72) Inventors: Dai HOMMA, Tokyo (JP); Kenji FUJISHIRO, Tokyo (JP)

(73) Assignee: TOKI CORPORATION

(21) Appl. No.: 15/917,226

(22) Filed: Mar. 9, 2018

(30) Foreign Application Priority Data
May 25, 2017 (JP) 2017-103598

(51) Int. Cl. F21V 8/00; H01L 33/48; G02B 6/35; F21V 14/02

(52) U.S. Cl. CPC G02B 6/0071; H01L 33/486; F21V 2200/00; G02B 6/3512; F21V 14/02; G02B 6/0031

(57) ABSTRACT

A light emitting device includes: a light source; a fixing part on which the light source is mounted; and a rotary light emitting part rotatably supported by the fixing part around a rotational axis Ax and provided such that a light axis of the light source is aligned with the rotational axis. The rotary light emitting part includes: a rod-shaped light guide having an incidence surface from which light from the light source enters and an exit surface from which the light guided inside exits, the rod-shaped light guide being arranged along the rotational axis Ax; a half mirror that changes a direction of light emitted from the exit surface of the rod-shaped light guide; and a light guide plate that receives light from the half mirror and emits light accordingly.

### BACKGROUND OF THE INVENTION

### 1. Field of the Invention

The present invention relates to a light emitting device.

### 2. Description of the Related Art

Light emitting devices capable of rotating a light emitting body provided with a light source such as an LED are known (see, for example, patent document 1).

[patent document 1] JP2016-58147

In the light emitting devices as mentioned above, there are cases where it is difficult to rotate the light emitting body as desired due to the electrical connection (cable, etc.) to the light source. For example, if the light emitting body is rotated continuously, the cables may be twisted, which may not only prevent desired rotation of the light emitting body but also result in disconnection in the cables.

### SUMMARY OF THE INVENTION

In this background, a purpose thereof is to provide a light emitting device capable of rotating a light emitting body as desired.

A light emitting device according to an embodiment of the present invention comprises: a light source; a fixing part on which the light source is mounted; and a rotary light emitting part rotatably supported by the fixing part around a rotational axis and provided such that a light axis of the light source is aligned with the rotational axis. The rotary light emitting part includes: a rod-shaped light guide having an incidence surface from which light from the light source enters and an exit surface from which the light guided inside exits, the rod-shaped light guide being arranged along the rotational axis; a light direction changing element that changes a direction of light emitted from the exit surface of the rod-shaped light guide; and a light emitting body that receives light from the light direction changing element and emits light accordingly.

A cross section of the rod-shaped light guide may be shaped in a regular polygon. The regular polygon may be a regular triangle, regular tetragon, or regular hexagon.

The exit surface of the rod-shaped light guide may include a frost finished part.

The light direction changing element may include a half mirror that transmits a portion of the light emitted from the exit surface of the rod-shaped light guide and reflects another portion of the light emitted from the exit surface of the rod-shaped light guide toward the light emitting body.

Optional combinations of the aforementioned constituting elements, and implementations of the invention in the form of methods, apparatuses, and systems may also be practiced as additional modes of the present invention.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a perspective cross-sectional view of an important part of a light emitting device according to an embodiment of the present invention;

FIG. 2 is an exploded perspective cross-sectional view of an important part of the light emitting device according to the embodiment of the present invention;

FIG. 3 is a lateral cross-sectional view of an important part of the light emitting device according to the embodiment of the present invention;

FIG. 4 is a schematic cross-sectional view of an important part of the light emitting device according to the embodiment of the present invention;

FIG. 5 is an exploded perspective view of an important part of the light emitting device according to the embodiment of the present invention;

FIG. 6 shows how light is emitted from the exit surface in the rod-shaped light guide having a circular cross section; and

FIG. 7 shows how light is emitted from the exit surface in the rod-shaped light guide having a square cross section.

### DETAILED DESCRIPTION OF THE INVENTION

The invention will now be described by reference to the preferred embodiments. This does not intend to limit the scope of the present invention, but to exemplify the invention.

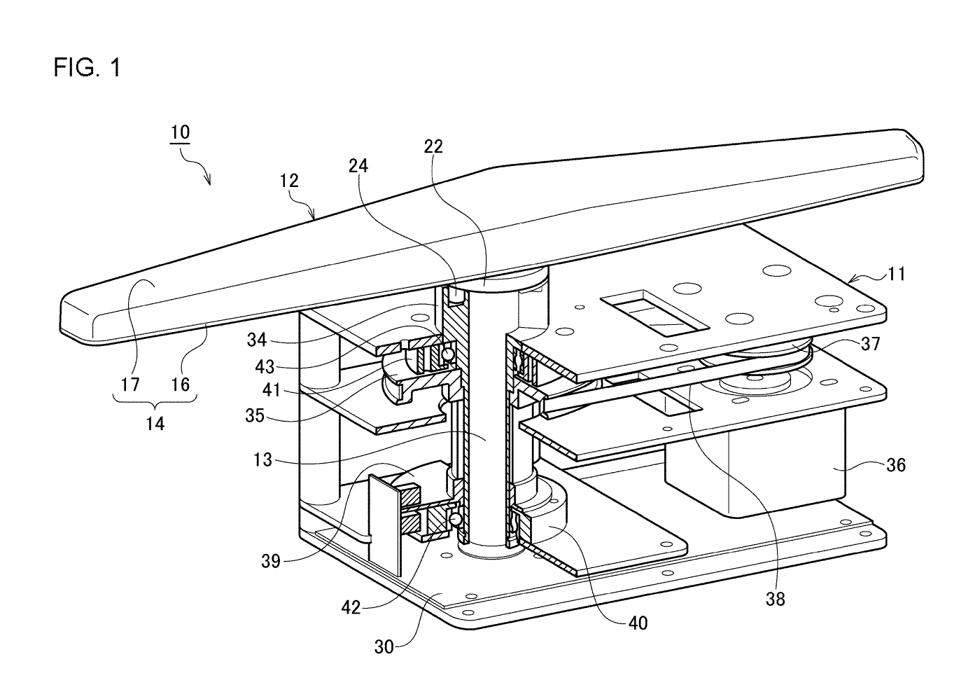

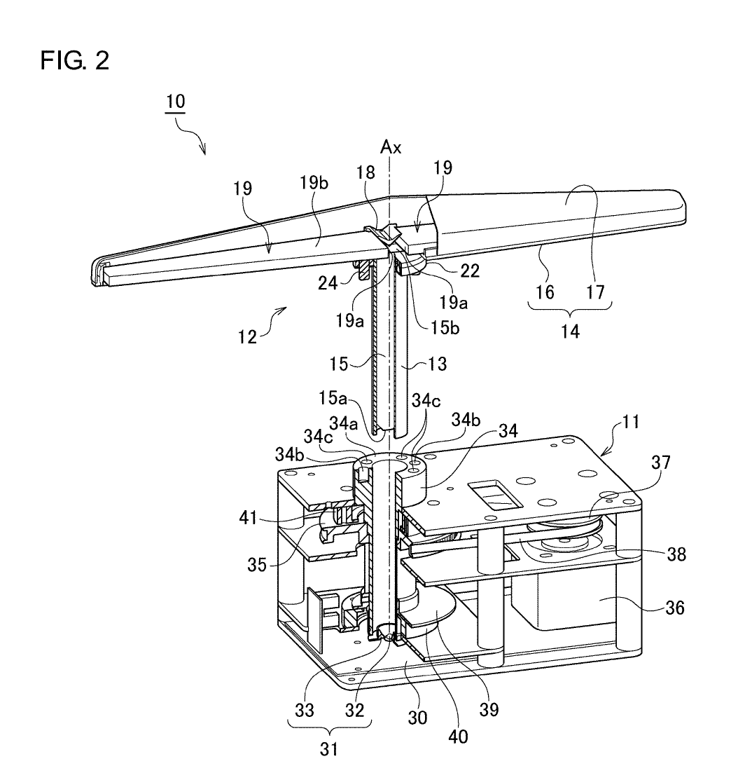

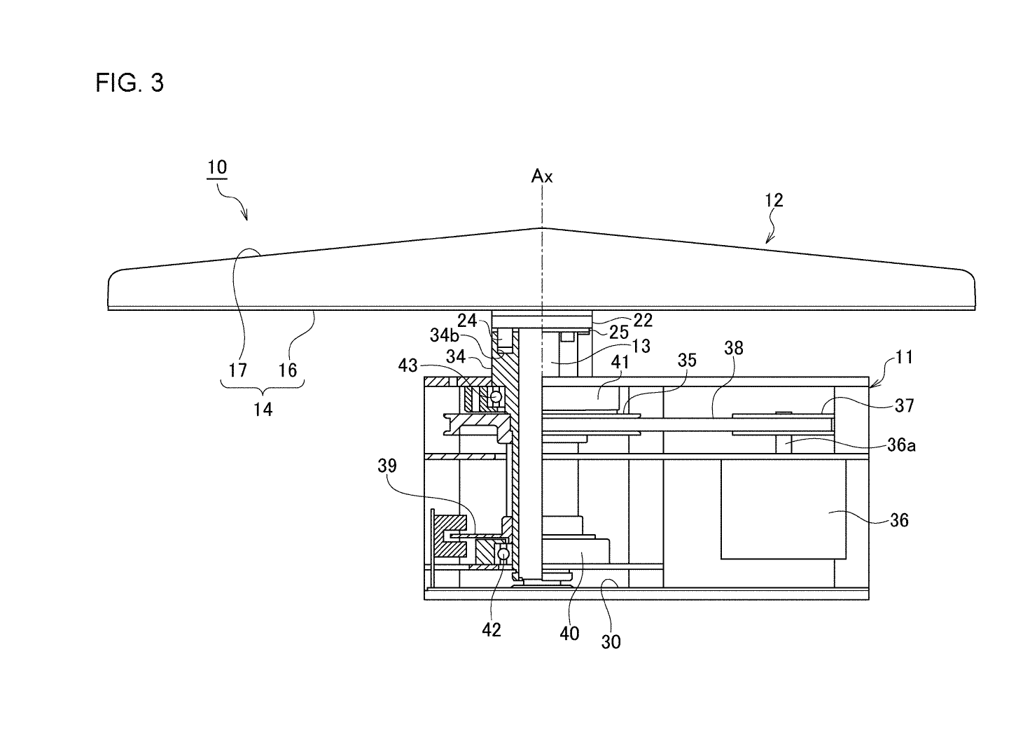

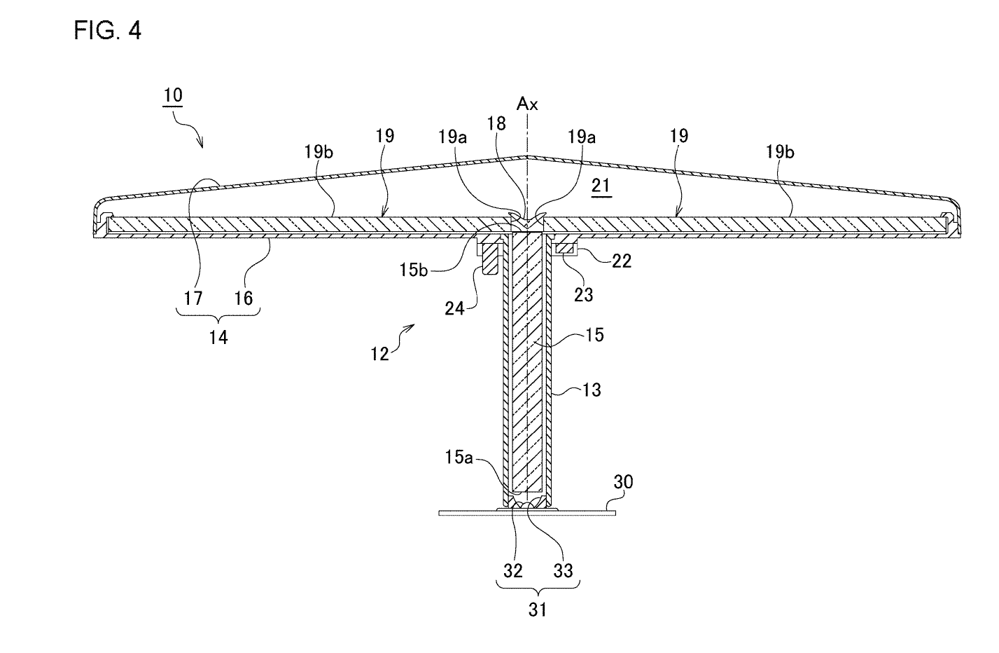

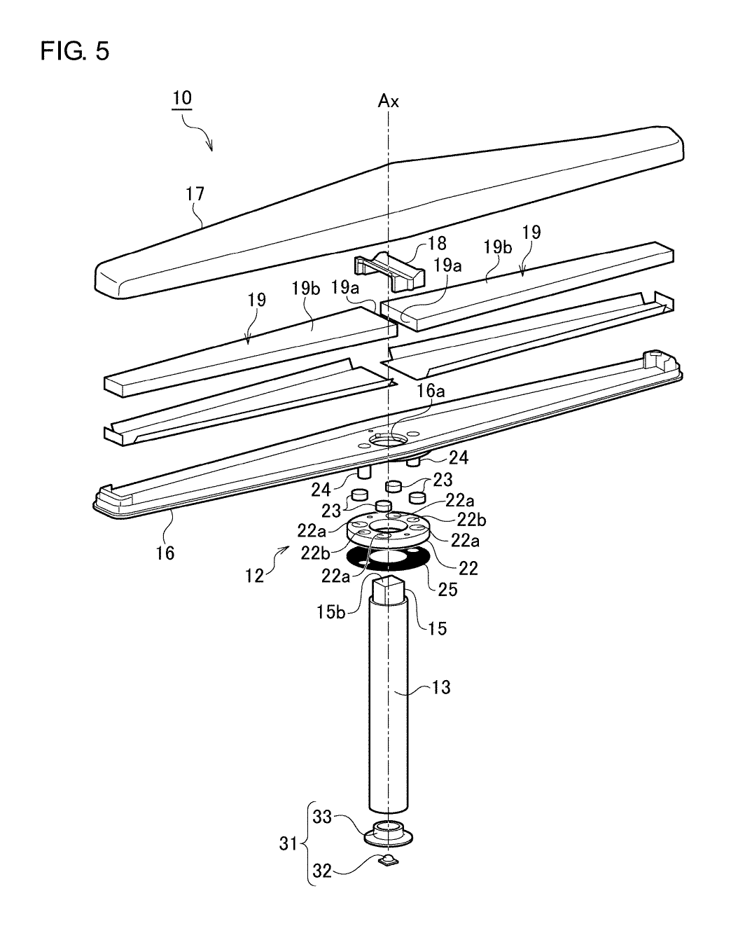

FIG. 1 is a perspective cross-sectional view of an important part of a light emitting device 10 according to an embodiment of the present invention. FIG. 2 is an exploded perspective cross-sectional view of an important part of the light emitting device 10 according to the embodiment of the present invention. FIG. 3 is a lateral cross-sectional view of an important part of the light emitting device 10 according to the embodiment of the present invention. FIG. 4 is a schematic cross-sectional view of an important part of the light emitting device 10 according to the embodiment of the present invention. FIG. 5 is an exploded perspective view of an important part of the light emitting device 10 according to the embodiment of the present invention.

The light emitting device 10 according to the embodiment includes a fixing part 11 and a rotary light emitting part 12 rotatably supported by the fixing part 11 around a rotational axis Ax.

A description will first be given of the rotary light emitting part 12. The rotary light emitting part 12 is a substantially T-shaped component and includes a hollow cylindrical shaft part 13 and a light emitting part housing 14 fixed to one end of the shaft part 13. The light emitting part housing 14 is a housing that extends in the direction perpendicular to the central axis of the shaft part 13. The rotary light emitting part 12 is supported by the fixing part 11 so as to be rotatable such that the central axis of the shaft part 13 is the rotational axis Ax.

A rod-shaped light guide 15 is provided inside the hollow cylindrical shaft part 13. The rod-shaped light guide 15 has an incidence surface 15a from which light from a light source enters and an exit surface 15b from which the light guided inside is emitted. The rod-shaped light guide 15 is arranged along the rotational axis Ax.

The light emitting part housing 14 is comprised of a body 16 and a cover 17 that covers the body 16. The body 16 and the cover 17 form an interior space 21. An end of the shaft part 13 is fixed to the center of the under surface of the body 16. A hole 16a is provided at the center of the under surface of the body 16 so that the interior space 21 of the light emitting part housing 14 and the interior of the shaft part 13 communicate. The hole 16a allows the exit surface 15b of the rod-shaped light guide 15 provided inside the shaft part 13 to be exposed in the interior space 21 of the light emitting part housing 14.

Four magnets 23 used to mount the rotary light emitting part 12 to the fixing part 11 and two rotation prevention pins 24 are provided at the center of the under surface of the body 16. The four magnets are fixed to the center of the under surface of the body 16 by a flange 22. The flange 22 is formed with four holes for accommodating the four magnets 23. The rotation prevention pins 24 project from the under surface of the body 16. The flange 22 is formed with through holes 22b in which the rotation prevention pins 24 extend through.

A half mirror 18 and two light guide plates 19, i.e., light emitting bodies, are provided in the interior space 21 of the light emitting part housing 14.

The half mirror 18 is provided at the center of the interior space 21 so as to face the exit surface 15b of the rod-shaped light guide 15. The half mirror 18 functions as a light direction changing element that changes the direction of the light emitted from the exit surface 15b of the rod-shaped light guide 15. The half mirror 18 transmits a portion of the light from the exit surface 15b of the rod-shaped light guide 15 and reflects another portion toward the light guide plate 19. In this embodiment, the half mirror 18 transmits a portion of the light from the exit surface 15b of the rod-shaped light guide 15 in the direction of the rotational axis Ax and reflects another portion in the direction perpendicular to the rotational axis Ax. The half mirror 18 has two reflecting surfaces that reflect portions of the light from the exit surface 15b of the rod-shaped light guide 15 in mutually opposite directions.

The two light guide plates 19 are arranged to extend in mutually opposite directions from the neighborhood of the center of the light emitting part housing 14. The light guide plate 19 receives the light from the half mirror 18 via the incidence surface 19a, guides the light inside, and emits the light from an exit surface 19b provided along a direction of extension. The light emitted from the exit surface 19b of the light guide plate 19 is transmitted through the cover 17 and radiated outside.

In the light emitting device 10 according to the embodiment, the light transmitted through the half mirror 18 and the light emitted from the light guide plate 19 are radiated outside from the cover 17. If a mere mirror is provided in place of the half mirror 18, the central portion of the rotary light emitting part 12 will be darker. By using the half mirror 18 as in this embodiment, the uniformity of brightness of illumination light is improved. The inner surface or outer surface of the cover 17 may be processed to scatter light in order to further improve the uniformity of brightness of illumination light. In addition to or in place of that, a light scattering member may be provided in the neighborhood of the inner surface of the cover 17.

A description will now be given of the fixing part 11. The fixing part 11 includes a base member 30 and a light source 31 mounted on the base member 30. The light source 31 is comprised of an LED 32 and a reflecting mirror 33 and is configured to emit light in a predetermined light axis direction. The LED 32 is provided such that the exit surface thereof is perpendicular to the light axis. The reflecting mirror 33 is configured to surround the LED 32 and reflects the light emitted from the LED 32 in the horizontal direction in a direction parallel to the light axis. The reflecting mirror 33 may have a reflecting surface shaped in a paraboloid of revolution. When the rotary light emitting part 12 is fitted to the fixing part 11, the light axis of the light source 31 is aligned with the rotational axis Ax of the rotary light emitting part 12.

The fixing part 11 further includes a hollow cylindrical rotary member 34 for supporting the rotary light emitting part 12 above the light source 31. The shaft part 13 of the rotary light emitting part 12 is inserted in the rotary member 34. The rotary member 34 is supported on the base member 30 by support members 40 and 41 so as to be rotatable around the rotational axis Ax. Bearings 42 and 43 are provided between the rotary member 34 and the support members 40 and 41.

Rotation prevention holes 34b are formed on an end face 34a of the rotary member 34 toward the rotary light emitting part. Four magnets 34c are provided on the end face 34a of the rotary member 34. When the shaft part 13 of the rotary light emitting part 12 is fully inserted into the rotary member 34, the rotation prevention pins 24 of the rotary light emitting part 12 are inserted into the rotation prevention holes 34b formed on the end face 34a of the rotary member 34 and the magnets 23 provided in the flange 22 of the rotary light emitting part 12 and the magnets 34c provided on the end face 34a of the rotary member 34 are attracted by a magnetic force, fixing the rotary light emitting part 12 to the rotary member 34.

While the rotary light emitting part 12 is being rotated, a large load is applied in the direction of rotation. For this reason, the rotation prevention pins 24 of the rotary light emitting part 12 are inserted into the rotation prevention holes 34b on the end face 34a of the rotary member 34. However, the flange 22 of the rotary light emitting part and the end face 34a of the rotary member 34 are merely placed in a contact so that noise or play may be created, and the durability will be lowered when the assembly repeatedly undergoes abrupt changes in the direction of rotation or speed. This is addressed in the light emitting device 10 according to the embodiment by sandwiching a thin rubber washer 25 between the end face 34a of the rotary member 34 and the flange 2 of the rotary light emitting part 12. The rubber washer 25 converts the attractive force of the magnets 23 and the magnets 34c into a large frictional force in the direction of rotation. The rotational load is supported in substance by the large frictional force. Further, the impact caused by the abrupt change in the rotation is absorbed by the rubber washer 25 so that noise can be prevented, and the life of the device can be extended. Still further, the rubber washer 25 also plays the role of preventing water from entering the fixing part 11 and protecting electronic components such as the LED 32.

The fixing part 11 further includes a rotary mechanism for rotating the rotary member 34 into which the rotary light emitting part 12 is inserted. The rotary mechanism includes a first pulley 35 fitted to the rotary member 34, a motor 36 provided on the base member 30, a second pulley 37 fitted to a shaft 36a of the motor 36, a belt 38 joining the first pulley 35 and the second pulley 37, and an encoder 39 for detecting the rotational position of the rotary member 34.

As the second pulley 37 fitted to the shaft 36a of the motor 36 is rotated, the belt 38 causes the first pulley 35 to rotate, causing the rotary member 34 and the rotary light emitting part 12 to be rotated around the rotational axis Ax. Thus, according to the embodiment, the rotary member 34 and the rotary light emitting part 12 are rotated without arranging the shaft 36a of the motor 36 coaxially with the rotational axis Ax, by using the first pulley 35, the second pulley 37, and the belt 38. This makes it easy to provide the light source 31 on the rotational axis Ax.

Rotation of the motor 36 is controlled by a control unit (not shown). For control, rotational position information on the rotary member 34 detected by the encoder 39 is used. The control unit may control light emission from the LED 32.

A description will be given of the operation of the light emitting device 10 configured as described above. The light from the light source 31 enters the rod-shaped light guide 15 via the incidence surface 15a. The light guided inside the rod-shaped light guide 15 is emitted from the exit surface 15b. A portion of the light emitted from the exit surface 15b is transmitted through the half mirror 18 and another portion is reflected by the half mirror 18 before entering the light guide plate 19 via the incidence surface 19a. The light guided inside the light guide plate 19 is emitted from the exit surface 19b. The light emitted from the exit surface 19b of the light guide plate 19 and the light transmitted through the half mirror 18 are transmitted through the cover 17 and radiated outside.

In the light emitting device 10 according to the embodiment, the light source 31 is fixed to the fixing part 11. Meanwhile, the rotary light emitting part 12 is rotatably supported by the fixing part 11 around the rotational axis Ax. No electric connection by, for example, a cable exists between the light source 31 and the rotary light emitting part 12. It is therefore possible to continuously rotate the rotary light emitting part 12 as desired without minding, for example, twisting of cables.

Since no electronic components are provided in the rotary light emitting part 12 itself, galvanic corrosion is prevented even when the rotary light emitting part 12 is installed in a place that could be hit by the rain. If the device is installed outdoors, frequent maintenance is expected. In the light emitting device 10 according to the embodiment, the rotary light emitting part 12 and the fixing part 11 are merely fixed by the magnetic force so that it is easy to remove the rotary light emitting part 12 from the fixing part 11. Accordingly, the light emitting device 10 is excellent in maintainability.

It will now be assumed that the an integrated RGB type LED is used as the LED 32 in the light emitting device 10. In an integrated RGB type LED, chips of the R, G, and B colors are arranged on a plane. Therefore, the positions of light emission of the RGB colors in the LED will be displaced from each other. If the light of the RGB colors with the displaced light emission positions is guided as it is in the rod-shaped light guide 15, the light of the RGB colors may be radiated from the exit surface 15b by maintaining the displacement, with the result that the appearance may become poor.

To prevent this situation, it is desired that the cross section of the rod-shaped light guide 15 be shaped in a regular polygon such as a regular triangle, regular tetragon, and regular hexagon. By shaping the cross section of the rod-shaped light guide 15 in a regular polygon, the light guided in the rod-shaped light guide 15 is uniformized according to a principle similar to that of a kaleidoscope. Accordingly, the displacement in between the RBG light is mitigated. Conversely, if the cross section of the rod-shaped light guide 15 is circular, the displacement in between the light on the incidence surface 15a is likely to be directly guided in the rod-shaped light guide 15.

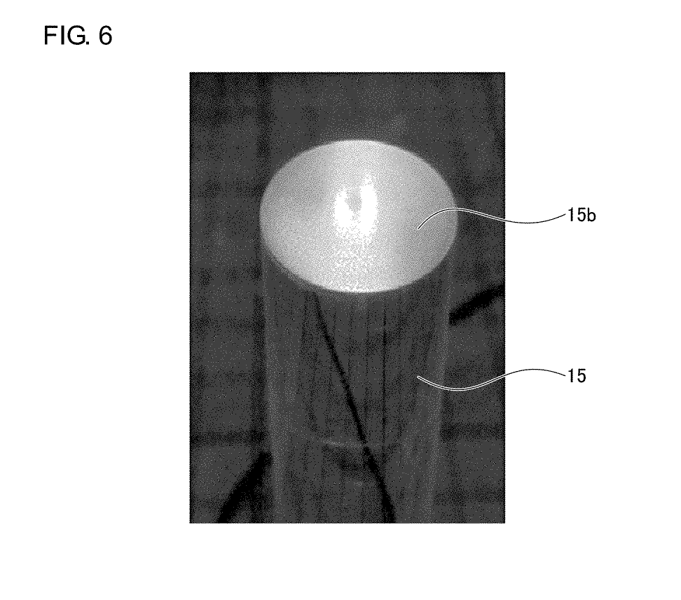

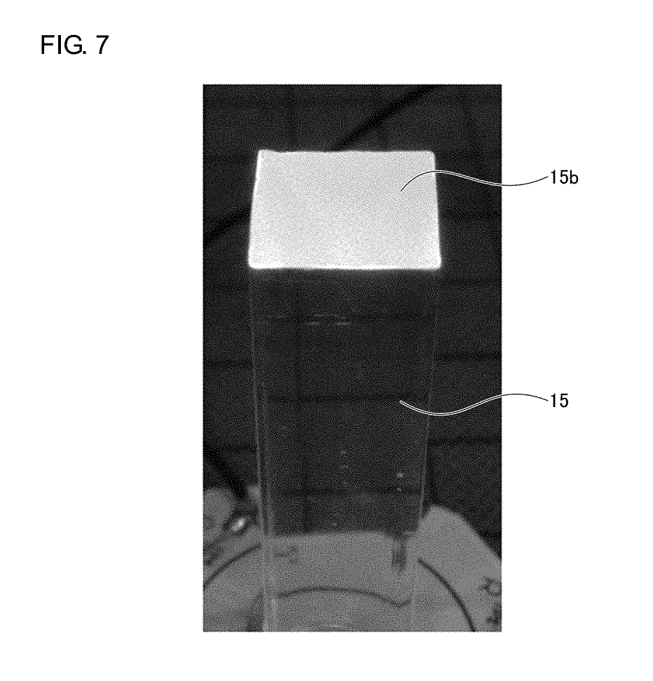

FIG. 6 shows how light is emitted from the exit surface 15b in the rod-shaped light guide 15 having a circular cross section. FIG. 7 shows how light is emitted from the exit surface 15b in the rod-shaped light guide 15 having a square cross section. FIGS. 6 and 7 show photos taken by causing the light from the light source using an integrated RGB type LED to be incident on the incidence surface of the rod-shaped light guide 15 and imaging the exit surface 15b of the rod-shaped light guide 15.

FIG. 6 shows an image of the LED near the center of the exit surface 15b, revealing that there a displacement in between the RGB light in the case of a circular cross section of the rod-shaped light guide 15. Meanwhile, FIG. 7 does not show an image of the LED, revealing that the RGB colors are averaged in the case of a square cross section of the rod-shaped light guide 15.

The exit surface 15b of the rod-shaped light guide 15 may be provided with a frost finished part in order to further average the displacement in between the RGB light. As described above, the displacement in between the RGB light can be averaged to a certain degree merely by shaping the cross section of the rod-shaped light guide 15 in a square. By providing a frost finished part in the exit surface 15b in addition to shaping the cross section of the rod-shaped light guide 15 in a square to further average the light emitted from the exit surface 15b, it is possible to create high-quality light in which the displacement between the emitted colors is further improved. Improvement in the displacement between the emitted colors is particularly important in an embodiment like the embodiment described above in which the light emitting body is rotated, for the purpose of representing high-quality of mixture of colors and beautiful light and dark contrast capable of meeting requirements for full-fledged decorative illumination.

Described above is an explanation based on an exemplary embodiment. The embodiment is intended to be illustrative only and it will be obvious to those skilled in the art that various modifications to constituting elements could be developed and that such modifications are also within the scope of the present invention.

For example, the two light guide plates 19 are provided to extend in mutually opposite directions in the embodiment described above. The embodiment is non-limiting as to the number and arrangement of the light guide plates 19. For example, five light guide plates may be arranged in a star array.

In the embodiment described above, the half mirror 18 is used as a light direction changing element. Alternatively, a prism may be provided in place of the half mirror 18.

What is claimed is:

1. A light emitting device comprising:
a light source;
a fixing part on which the light source is mounted; and
a rotary light emitting part rotatably supported by the fixing part around a rotational axis and provided such that a light axis of the light source is aligned with the rotational axis, wherein
the rotary light emitting part includes:
a rod-shaped light guide having an incidence surface from which light from the light source enters and an exit surface from which the light guided inside exits, the rod-shaped light guide being arranged along the rotational axis;
a light direction changing element that changes a direction of light emitted from the exit surface of the rod-shaped light guide; and
a light emitting body that receives light from the light direction changing element and emits light accordingly.

2. The light emitting device according to claim 1, wherein
a cross section of the rod-shaped light guide is shaped in a regular polygon.

3. The light emitting device according to claim 2, wherein
the regular polygon is a regular triangle, regular tetragon, or regular hexagon.

4. The light emitting device according to claim 1, wherein
the exit surface of the rod-shaped light guide includes a frost finished part.

5. The light emitting device according to claim 1, wherein
the light direction changing element includes a half mirror that transmits a portion of the light emitted from the exit surface of the rod-shaped light guide and reflects another portion of the light emitted from the exit surface of the rod-shaped light guide toward the light emitting body.
